(19) United States
(12) Patent Application Publication
(10) Pub. No.: US 2026/0264165 A1
(43) Pub. Date: Sep. 10, 2026

(54) METHODS OF CUTTING A WIRE ON A WIRE BONDING SYSTEM, AND RELATED CUTTING BLADES AND WIRE BONDING SYSTEMS

(71) Applicant: Kulicke and Soffa Industries, Inc., Fort Washington, PA (US)

(72) Inventors: Tao Xu, Irvine, CA (US); Jose de Jesus Lozano De Alva, Lake Forest, CA (US); Robert Ito, Irvine, CA (US); Frank Daniels, JR., Irvine, CA (US); Yahia Benhacene, El Cajon, CA (US); Stanley Tang, Irvine, CA (US)

(73) Assignee: Kulicke and Soffa Industries, Inc., Fort Washington, PA (US)

(21) Appl. No.: 19/166,927

(22) PCT Filed: Apr. 9, 2024
(86) PCT No.: PCT/US2024/023733

§ 371 Date: Sep. 19, 2025

Related U.S. Application Data
(60) Provisional application No. 63/461,352, filed on Apr. 24, 2023.

(51) Int. Cl. B23K 20/00; B23K 20/26; B23K 101/40; H10W 72/00

(52) U.S. Cl. CPC B23K 20/004; B23K 20/26; H10W 72/07163; H10W 72/07178; H10W 72/07183; B23K 2101/40

(57) ABSTRACT

A wire bonding system is provided herein. The wire bonding system includes a bonding tool. The wire bonding system also includes a cutting blade disposed adjacent to the bonding tool. The cutting blade defines a face on a side of the cutting blade adjacent a tip of the cutting blade. The face is configured to contact wire prior to a cutting operation.

### CROSS-REFERENCE TO RELATED APPLICATION

This application is a U.S. National Stage under 35 USC 371 from PCT application No. PCT/US2024/023733 filed Apr. 9, 2024, which claims the benefit of U.S. Provisional Application No. 63/461,352, filed Apr. 24, 2023, the content of both of which is incorporated herein by reference.

### FIELD

The invention relates to wire (including ribbon) bonding operations, and more particularly, to cutting blades used in connection with such operations.

### BACKGROUND

In the processing and packaging of semiconductor devices, wire bonding continues to be a widely used method of electrical interconnection between two locations within a package (e.g., between a die pad of a semiconductor die and a lead of a leadframe). In connection with the formation of wire and/or ribbon loops in certain applications, a cutting blade may be used to cut into the conductive material (e.g., a round cross section wire, a ribbon shaped wire, etc.) to assist in severing the completed wire loop from the wire supply. U.S. Pat. Nos. 4,976,392 and 8,141,765, which relate to wire bonding systems, disclose use of such a cutting blade and are incorporated by reference herein in their entirety.

It would be desirable to provide improved methods of cutting a wire on a wire bonding system, and improved cutting blades and associated wire bonding systems.

### SUMMARY

According to an exemplary embodiment of the invention, a wire bonding system is provided. The wire bonding system includes a bonding tool (e.g., a wire bonding tool, a wedge bonding tool also known as a wedge, etc.). The wire bonding system also includes a cutting blade disposed adjacent to the bonding tool. The cutting blade defines a face on a side of the cutting blade adjacent a tip of the cutting blade. The face is configured to contact wire prior to a cutting operation.

According to other embodiments of the invention, the wire bonding system recited in the immediately preceding paragraph may have any one or more of the following features: after a wire bonding operation is complete, the cutting blade is configured to contact the bonding tool prior to the cutting operation; after a wire bonding operation is complete, the cutting blade is configured to contact the bonding tool during the cutting operation; the face is configured to provide resistance to the cutting blade to prevent overcut of a wire; the cutting blade defines another side, the another side facing the bonding tool, the another side being opposite the side, the side defining another face adjacent the face, the face and the another face meeting at an area of intersection, the face and the another face being non-parallel to each other; the cutting blade defines another side, the another side facing the bonding tool, the another side being opposite the side, the side defining another face adjacent the face, the face being configured at a first angle with respect to a vertical axis on the wire bonding system, the another face being configured at a second angle with respect to the vertical axis of the wire bonding system, the first angle being different from the second angle; the first angle is greater than the second angle; further including a wire guide configured to direct a wire toward a position beneath the bonding tool, wherein after formation of a wire loop but before a cutting operation, a wire portion adjacent the tip of the cutting blade defines a third angle with respect to the vertical axis of the wire bonding system, the first angle being greater than the third angle further including a monitoring system for monitoring a resistance characteristic of the cutting blade as the cutting blade cuts into a wire on the wire bonding system; further including a motion system configured to raise and lower the cutting blade for cutting a wire on the wire bonding system; the resistance characteristic is related to an electrical characteristic of the motion system; the resistance characteristic is related to at least one of an electrical current of the motion system, a velocity of a portion of the motion system, and a position of a portion of the motion system; the motion system is configured to stop lowering of the cutting blade upon the resistance characteristic reaching a predetermined value; and/or the tip includes a stepped portion configured to limit penetration of the cutting blade into a wire during a cutting operation.

According to another exemplary embodiment of the invention, a wire bonding system is provided. The wire bonding system includes a bonding tool. The wire bonding system also includes a cutting blade disposed adjacent to the bonding tool. The cutting blade defines a first side and a second side. The first side faces the bonding tool. The second side is opposite the first side. The second side defines a first flat portion adjacent a tip of the cutting blade, and a second flat portion adjacent the first flat portion. The first flat portion and the second flat portion meet at an area of intersection. The first flat portion and the second flat portion are non-parallel to each other. The area of intersection is configured to contact wire prior to a cutting operation.

According to other embodiments of the invention, the wire bonding system recited in the immediately preceding paragraph may have any one or more of the following features: after a wire bonding operation is complete, the cutting blade is configured to contact the bonding tool prior to the cutting operation; after a wire bonding operation is complete, the cutting blade is configured to contact the bonding tool during the cutting operation; the first flat portion is configured to provide resistance to the cutting blade to prevent overcut of a wire; the first flat portion is configured at a first angle with respect to a vertical axis on the wire bonding system, and the second flat portion is configured at a second angle with respect to the vertical axis of the wire bonding system, the first angle being different from the second angle; the first angle is greater than the second angle; further including a wire guide configured to direct a wire toward a position beneath the bonding tool, wherein after formation of a wire loop but before the cutting operation, a wire portion adjacent the tip of the cutting blade defines a third angle with respect to the vertical axis of the wire bonding system, the first angle being greater than the third angle; further including a monitoring system for monitoring a resistance characteristic of the cutting blade as the cutting blade cuts into a wire on the wire bonding system; further including a motion system configured to raise and lower the cutting blade for cutting the wire on the wire bonding system; the resistance characteristic is related to an electrical characteristic of the motion system; the resistance characteristic is related to at least one of an electrical current of the motion system, a velocity of a portion of the motion system, and a position of a portion of the motion system; the motion system is configured to stop lowering of the cutting blade upon the resistance characteristic reaching a predetermined value; and/or the tip includes a stepped portion configured to limit penetration of the cutting blade into a wire during a cutting operation.

According to yet another exemplary embodiment of the invention, a wire bonding system is provided. The wire bonding system includes a bonding tool. The wire bonding system also includes a cutting blade disposed adjacent to the bonding tool. The cutting blade defines a first side and a second side. The first side faces the bonding tool. The second side is opposite the first side. The second side defines a first flat portion adjacent a tip of the cutting blade, and a second flat portion adjacent the first flat portion. The first flat portion is configured at a first angle with respect to a vertical axis on the wire bonding system. The second flat portion is configured at a second angle with respect to the vertical axis of the wire bonding system. The first angle is different from the second angle. The first flat portion and the second flat portion meet at an area of intersection, where the area of intersection is configured to contact wire prior to a cutting operation.

According to other embodiments of the invention, the wire bonding System recited in the immediately preceding paragraph may have any one or more of the following features: after a wire bonding operation is complete, the cutting blade is configured to contact the bonding tool prior to the cutting operation; after a wire bonding operation is complete, the cutting blade is configured to contact the bonding tool during the cutting operation; the first flat portion is configured to provide resistance to the cutting blade to prevent overcut of a wire; the first angle is greater than the second angle; further including a monitoring system for monitoring a resistance characteristic of the cutting blade as the cutting blade cuts into a wire on the wire bonding system; further including a motion system configured to raise and lower the cutting blade for cutting the wire on the wire bonding system; the resistance characteristic is related to an electrical characteristic of the motion system; the resistance characteristic is related to at least one of an electrical current of the motion system, a velocity of a portion of the motion system, and a position of a portion of the motion system; the motion system is configured to stop lowering of the cutting blade upon the resistance characteristic reaching a predetermined value; the tip includes a stepped portion configured to limit penetration of the cutting blade into a wire during a cutting operation; and/or further including a wire guide configured to direct a wire toward a position beneath the bonding tool, wherein after formation of a wire loop but before the cutting operation, a wire portion adjacent the tip of the cutting blade defines a third angle with respect to the vertical axis of the wire bonding system, the first angle being greater than the third angle.

According to yet another exemplary embodiment of the invention, a method of cutting a wire in connection with a wire bonding system is provided. The method includes the steps of: (a) providing a bonding tool; (b) providing a cutting blade adjacent the bonding tool; (c) moving the cutting blade to contact a portion of the wire; and (d) cutting another portion of the wire away from the portion of the wire.

According to other embodiments of the invention, the method recited in the immediately preceding paragraph may have any one or more of the following features: step (c) includes contacting the bonding tool with the cutting blade prior to step (d); step (c) includes contacting the bonding tool with the cutting blade during step (d); further including the step of (e) providing a monitoring system to monitor a resistance characteristic of the cutting blade during step (d); and/or further including the step of terminating step (d) upon the resistance characteristic reaching a predetermined value.

According to yet another exemplary embodiment of the invention, a cutting blade for a wire bonding system is provided. The cutting blade includes: a body portion extending to a tip portion, the tip portion including a first side and a second side, the first side defining a first face and a second face, the first face and the second face being non-parallel to each other.

According to other embodiments of the invention, the cutting blade recited in the immediately preceding paragraph may have any one or more of the following features: at least one of the first face and the second face is configured to provide resistance to the cutting blade to prevent overcut of a wire; the first face is adjacent to a tip of the tip portion, the first face being configured to provide resistance to the cutting blade to prevent overcut of a wire; the first face is adjacent to a tip of the tip portion, wherein the first face is configured at a first angle with respect to a vertical axis, the second face being configured at a second angle with respect to the vertical axis, the first angle being different from the second angle; the first angle is greater than the second angle; the cutting blade is configured to contact a wire portion adjacent the tip of the cutting blade after formation of a wire loop but before a cutting operation, the wire loop defining a third angle with respect a vertical axis, the first angle being greater than the third angle; the tip portion includes a stepped portion configured to limit penetration of the cutting blade into a wire during a cutting operation; and/or the stepped portion defines a step width such that a control signal of a monitoring system, used in connection with the cutting blade, can be monitored.

According to yet another exemplary embodiment of the invention, another cutting blade for a wire bonding system is provided. The cutting blade includes: a body portion extending to a tip portion, the tip portion including a first side and a second side, the first side defining a first face and a second face, the first face and the second face defining a point of intersection, the point of intersection configured to contact a wire during a cutting operation.

According to other embodiments of the invention, the cutting blade recited in the immediately preceding paragraph may have any one or more of the following features: at least one of the first face and the second face is configured to provide resistance to the cutting blade to prevent overcut of a wire; the first face is adjacent to a tip of the tip portion, the first face being configured to provide resistance to the cutting blade to prevent overcut of a wire; the first face is adjacent to a tip of the tip portion, wherein the first face is configured at a first angle with respect to a vertical axis, the second face being configured at a second angle with respect to the vertical axis, the first angle being different from the second angle; the first angle is greater than the second angle; the cutting blade is configured to adjust a wire portion adjacent the tip of the cutting blade after formation of a wire loop but before a cutting operation, the wire loop defining a third angle with respect a vertical axis, the first angle being greater than the third angle; the tip portion includes a stepped portion configured to limit penetration of the cutting blade into a wire during a cutting operation; and/or the stepped portion defines a step width such that a control signal of a monitoring system, used in connection with the cutting blade, can be monitored.

According to yet another exemplary embodiment of the invention, yet another cutting blade for a wire bonding system is provided. The cutting blade includes: a body portion extending to a tip portion, the tip portion including a first side and a second side, the first side defining a first face and a second face, the first face being disposed at a first angle with respect to a vertical axis, and the second face being disposed as a second angle with respect to the vertical axis, the second angle being different from the first angle.

According to other embodiments of the invention, the cutting blade recited in the immediately preceding paragraph may have any one or more of the following features: at least one of the first face and the second face is configured to provide resistance to the cutting blade to prevent overcut of a wire; the first face is adjacent to a tip of the tip portion, the first face being configured to provide resistance to the cutting blade to prevent overcut of a wire; the first face is adjacent to a tip of the tip portion, wherein the first angle is greater than the second angle; the cutting blade is configured to adjust a wire portion adjacent the tip of the cutting blade after formation of a wire loop but before a cutting operation, the wire loop defining a third angle with respect a vertical axis, the first angle being greater than the third angle; the tip portion includes a stepped portion configured to limit penetration of the cutting blade into a wire during a cutting operation; and/or the stepped portion defines a step width such that a control signal of a monitoring system, used in connection with the cutting blade, can be monitored.

According to yet another exemplary embodiment of the invention, yet another cutting blade for a wire bonding system is provided. The cutting blade includes: a body portion extending to a tip portion, the tip portion including a first side and a second side, the first side defining a first face and a second face, the tip portion further including a stepped portion configured to limit penetration of the cutting blade into a wire during a cutting operation.

According to other embodiments of the invention, the cutting blade recited in the immediately preceding paragraph may have any one or more of the following features: at least one of the first face and the second face is configured to provide resistance to the cutting blade to prevent overcut of a wire; the first face is adjacent to a tip of the tip portion, the first face being configured to provide resistance to the cutting blade to prevent overcut of a wire; the first face is configured at a first angle with respect to a vertical axis, the second face being configured at a second angle with respect to the vertical axis, the first angle being different from the second angle; the first face is adjacent to a tip of the tip portion, wherein the first angle is greater than the second angle; the cutting blade is configured to contact a wire portion adjacent the tip of the cutting blade after formation of a wire loop but before a cutting operation, the wire loop defining a third angle with respect a vertical axis, the first angle being greater than the third angle; the stepped portion defines a step width such that a control signal of a monitoring system, used in connection with the cutting blade, can be monitored; and/or the stepped portion defines a step height such the cutting blade tip can cut to a predefined percentage of a wire diameter.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIG. 1 is a block diagram side view illustrating a wire bonding system for bonding a wire (e.g., a round wire, a ribbon shaped wire, etc.) in accordance with an exemplary embodiment of the invention;

FIGS. 2A-2D are side sectional views of elements of a wire bonding system illustrating a cutting operation in accordance with an exemplary embodiment of the invention;

FIGS. 3A-3G are side sectional and block diagram views of elements of a wire bonding system illustrating cutting operations in accordance with one or more exemplary embodiments of the invention;

FIGS. 4A-4D are side sectional and block diagram views of elements of another wire bonding system illustrating a cutting operation in accordance with an exemplary embodiment of the invention;

FIG. 5 is a side sectional and block diagram view of elements of yet another wire bonding system in accordance with an exemplary embodiment of the invention;

FIG. 6 is a side sectional and block diagram view of elements of yet another wire bonding system in accordance with an exemplary embodiment of the invention; and

FIG. 7 is a flow diagram illustrating a method of cutting a wire in connection with a wire bonding system in accordance with an exemplary embodiment of the invention.

### DETAILED DESCRIPTION

The terms “wire”, “ribbon”, and “conductive material” are used herein to generically describe the material bonded by a wire bonding system (e.g., a wedge bonding system). It is understood that a wire bonding system may bond a wire material, or a ribbon material, as is desired in the given application. Thus, it is understood that these terms are used interchangeably and are not intended to be limiting with respect to one another. For example, as used herein, the term “wire” is intended to refer to a round wire (i.e., a wire having a round cross section), a ribbon shaped wire, and others.

Wire bonding is widely used as a reliable and cost-effective interconnect method in semiconductor packaging. In wedge bonding (including ribbon bonding) after a last bond is finished, wire is sometimes cut using a cutting blade. There are generally two ways to cut wire in many wire bonding processes: a rear-cut application and front-cut application. For a front-cut application, the cutter and wire guide are placed at different sides of the bonding tool; for a rear-cut application, the cutter and wire guide are at the same side. A predetermined cut depth may be defined prior to a bonding operation such that the bonding process can be continued in a desired operation. For the front-cut application, the cut depth may be predetermined to be ≥ 100% of the wire diameter. A rear-cut application may need a more accurate cut process.

In order to have a stable and controlled cutting process, the cutting blade (e.g., cutting blade 112) may desirably be very close to (and possibly even in contact with) the bonding tool when the cutting blade moves down and cuts into the wire (e.g., wire 116) at a desired cutting point. Due to process variations, the cutting blade may not always contact the bonding tool. Further, the cutting blade may sometimes cut into the wire at an undesired point resulting in an unstable cut depth and tail length. When the cut depth is less than a predetermined threshold (e.g., <65% of the wire diameter or the “shallow limit”), the wire cannot be terminated, and the bonding process may stop. When the cut depth is greater than another predetermined threshold (e.g., >85% of the wire diameter or the “deep limit”), the wire cannot be fed under the bonding tool and bonding process may also stop. In certain embodiments, the “cut window” can be defined as the value difference between the maximum value of the cut depth adjustment (e.g., a parameter defining the cut depth of the cutting blade) and the minimum value of the cut depth adjustment. A small cut window makes the cutting process unstable and challenging. A larger cut window is usually desired.

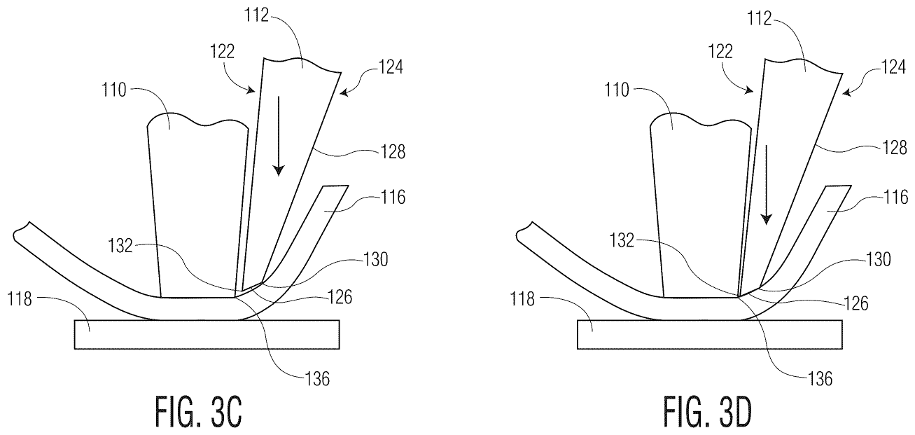

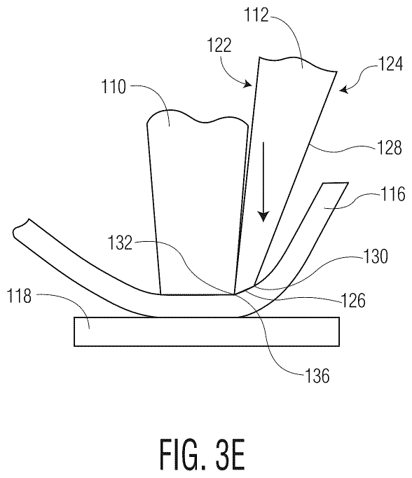

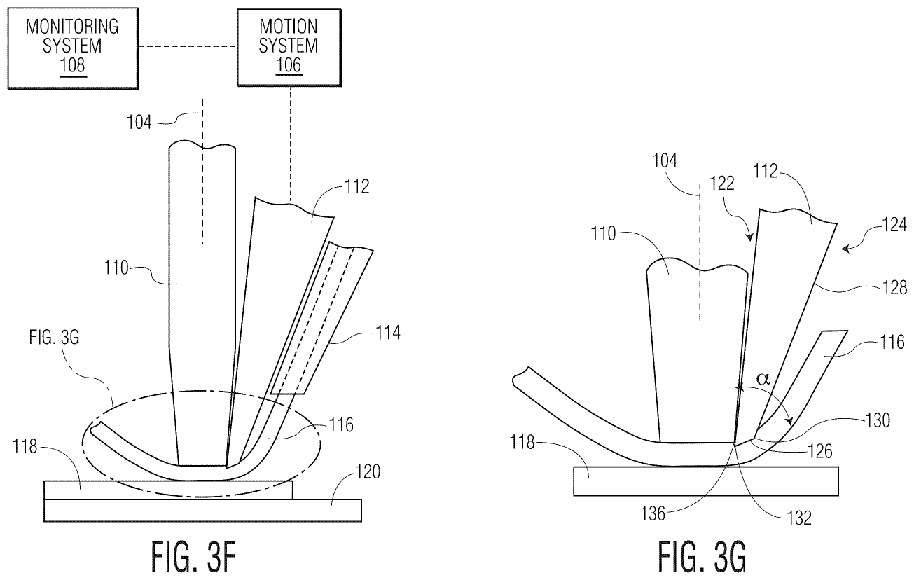

Certain embodiments illustrated and described herein provide a unique tip geometry design to ensure a large cut window and a consistent cut location. Such embodiments can result in consistent wire tail lengths and/or a consistent cut depth so that a stable cutting process can be achieved. The wire coming out of a wire guide has an angle Ø (e.g., ~40°, 20° to 60°, etc.) (e.g., see FIG. 3B) with respect to a vertical axis of a wire bonding machine. To prevent a tip of the cutting blade from cutting into the wire before it reaches a desired cutting point, a face near the tip of cutting blade may have an angle α (e.g., ~60°, 40° to 80°, etc.) (e.g., see FIG. 3B) that is larger than the wire angle Ø. An optimal angle α, and a width of the “face” ensures the cutting blade slides along the wire at the face and/or intersection point (e.g., a “corner”) of the cutting blade before the tip reaches the cut location (e.g., cut location 136). Although there are many variations in the process (e.g., setup, vibration, etc.), the cutting blade tip desirably cuts into the wire at an optimal cut location (e.g., cut location 136), resulting in a consistent cut depth and tail length. Further, the design of the face adds more resistance to the cutting blade and prevents over-cut (i.e., cutting beyond the deep limit) when the tip is close to the deep limit, resulting in a larger (e.g., >2×) cut window. The optimal width of the face can also eliminate an undesired imprint at wire, which can show at the first bond of the next wire in a next bonding operation.

In certain embodiments, a cutting blade includes a step (e.g., a stepped portion) as in U.S. Pat. No. 8,141,765. The step height (e.g., step height 140) can be designed as a percentage of the wire diameter so that the cutting blade tip can cut to a predefined percentage of the wire diameter (e.g., 75%), or within a desired cut depth rage (e.g., 65% to 85% of wire diameter). The step width (e.g., step width 142) has several functions, including physically preventing the cutting blade from going deeper into the wire and generating a motion control signal to stop the drive of a cutting motion. Before the step width touches the wire, the tip of the cutting blade can cut smoothly into the wire, and resistance to further cutting can be detected (e.g., using a monitoring system). When the step touches the wire, the step width rapidly generates an increased resistance preventing the tip from going deeper. However, for some motion control systems, the driving force that moves the cutting blade downwards can be much larger than the resistant force generated from the stepped width. As a result, the step width may not effectively stop the cutting. For such motion control systems, a control signal may desirably be used to stop the driving force so that the cutting blade will stop moving.

Many types of control signals can be monitored. For example, an electrical motor current may be monitored (e.g., the current of a motion system used to raise and lower the cutting blade), thereby monitoring a resistance characteristic (e.g., a resistance characteristic of the cutting blade as the cutting blade cuts into a wire on the wire bonding system). Such control signals may be monitored for the various cutting blades within the scope of the invention (not just cutting blades with a step). If the resistance suddenly increases (e.g., as the result of the step width touching the wire, as a result of a point of intersection touching the wire, as a result of a face of the cutting blade touching the wire, etc.), the driving force (e.g., the lowering of the cutting blade) can be set to 0 and the cut process stops.

In accordance with certain aspects of the invention, the step width may be optimized. To generate a strong signal, a large step width is desired. However, too wide a step width pushes the cutting blade tip far away from the bonding tool edge, reducing the efficiency of the cutting process. A small step width (e.g., step width 142) allows an efficient cutting process, but the control signal could be too small to accurately stop the cut process.

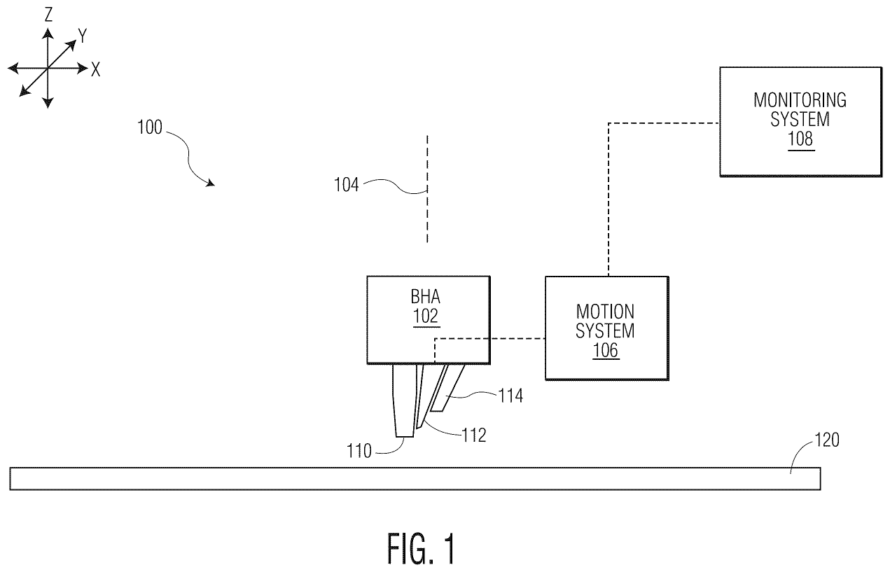

Referring now to the drawings, in FIG. 1 a wire bonding system 100 is illustrated. Wire bonding system 100 is illustrated defining a vertical axis 104. Wire bonding system 100 includes a bond head assembly 102. Bond head assembly 102 is illustrated supporting (or including) a bonding tool 110 (e.g., a wire bonding tool, a wedge bonding tool also known as a wedge, etc.), a cutting blade 112 (disposed adjacent to bonding tool 110), and a wire guide 114. Wire bonding system 100 also includes a support structure 120 for supporting a workpiece (e.g., a substrate, a semiconductor element, a die, a chip, etc.). Wire bonding system 100 also includes a motion system 106 and a monitoring system 108. Motion system 106 is configured to raise and lower cutting blade 112 for cutting wire on wire bonding system 100. Monitoring system 108 (e.g., including a computer, a processor, or the like) monitors a resistance characteristic of cutting blade 112 (e.g., as cutting blade 112 cuts into a wire on wire bonding system 100). Examples of such a resistance characteristic may be: an electrical characteristic of motion system 106 (e.g., an electrical current associated with motion system 106); a velocity of a portion of the motion system (e.g., a portion of the motion system that may include and/or carry cutting blade 112); a position of a portion of the motion system (e.g., a portion of the motion system that may include and/or carry cutting blade 112); etc. Monitoring system 108 may be configured to stop lowering of cutting blade 112 upon the resistance characteristic reaching a predetermined value.

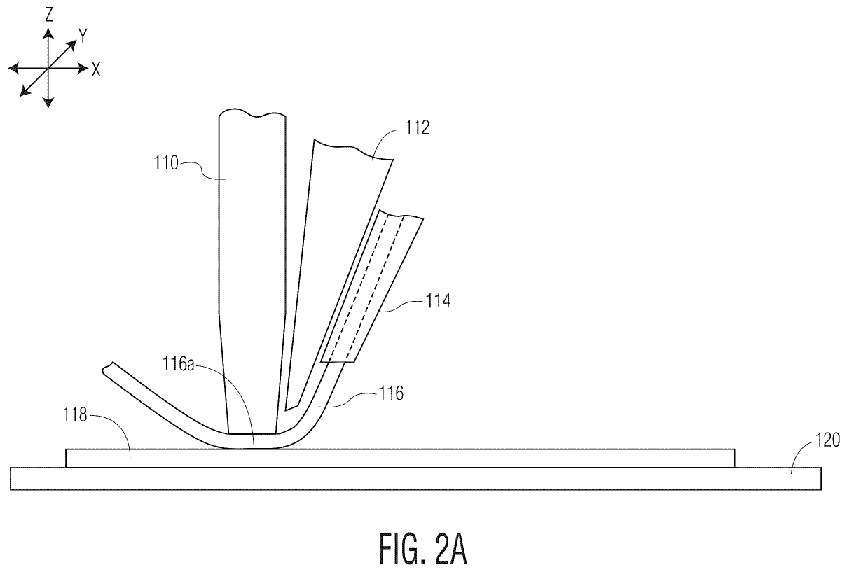

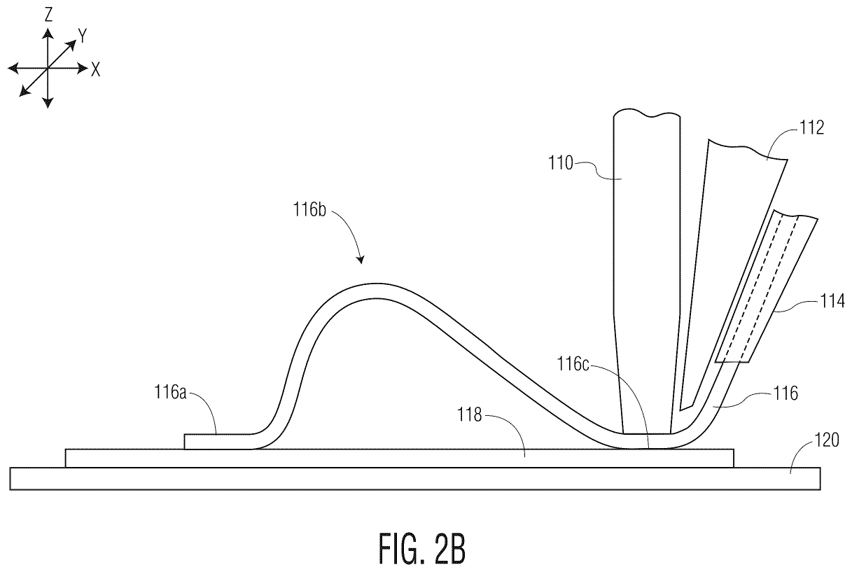

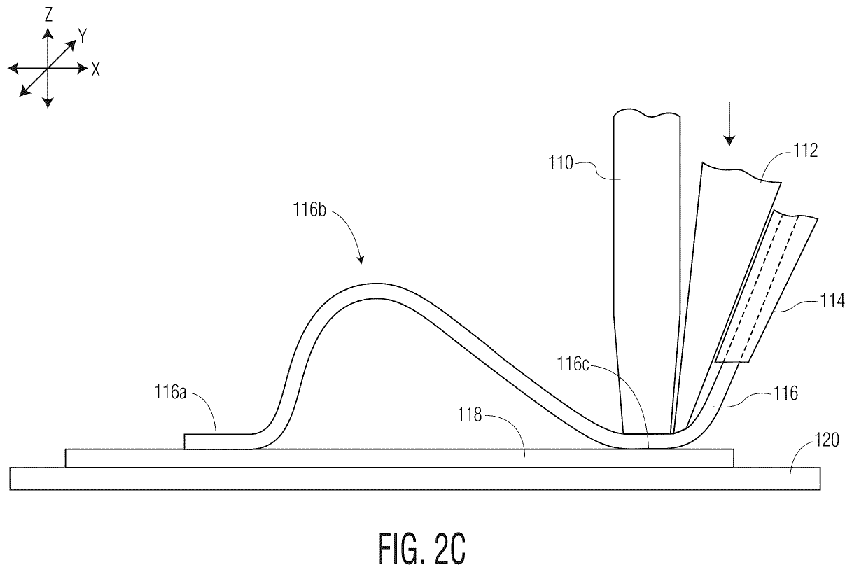

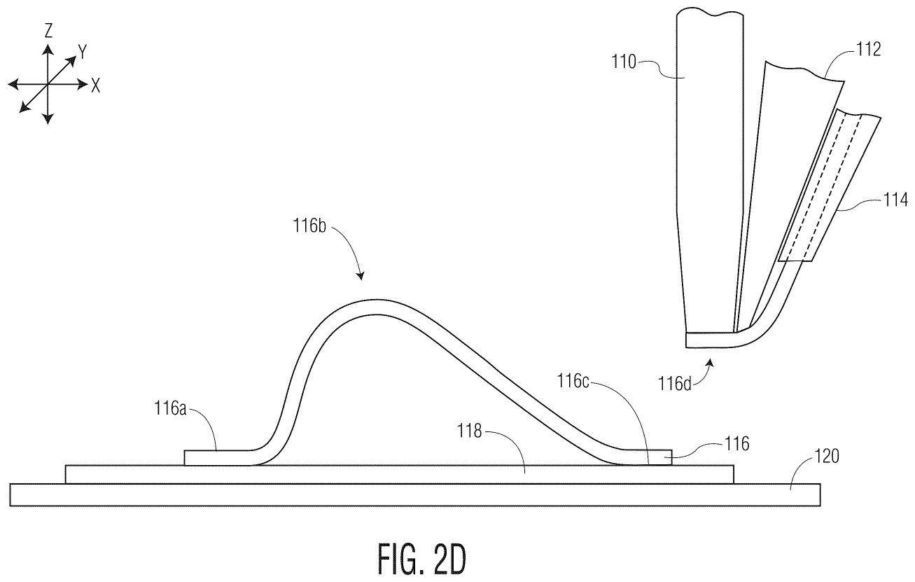

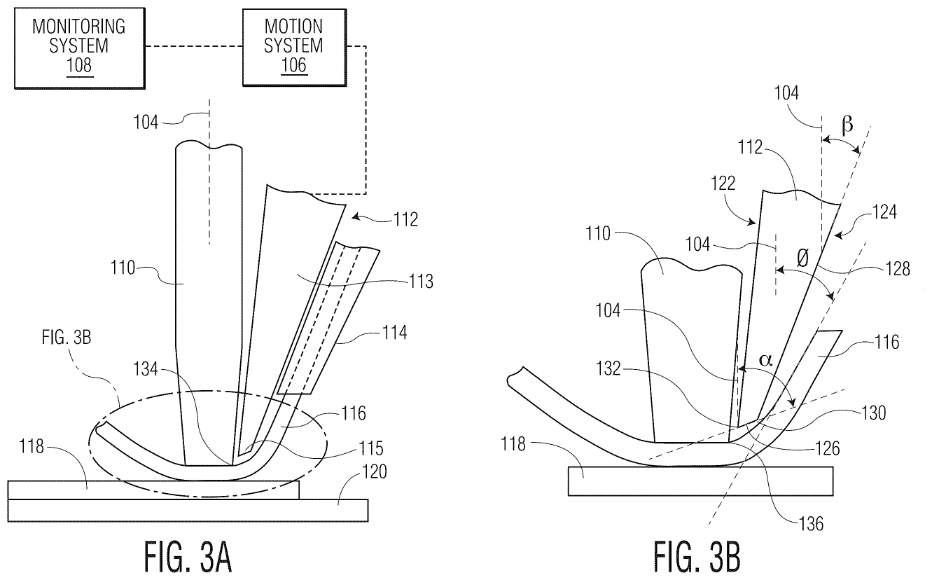

In each of FIGS. 2A-2D, FIGS. 3A-3G, FIGS. 4A-4D, FIG. 5, and FIG. 6, details of exemplary elements of a wire bonding system in accordance with exemplary embodiments of the invention are shown. Thus, each of these examples (FIGS. 2A-2D, FIGS. 3A-3G, FIGS. 4A-4D, FIG. 5, and FIG. 6) may be part of the more generic wire bonding system 100 illustrated in FIG. 1.

Referring now to FIGS. 2A-2D, lower portions of each of a bonding tool 110, a cutting blade 112, and a wire guide 114 are illustrated. In FIGS. 2A-2D, a wire loop is formed, and a cutting operation is completed. Referring specifically to FIG. 2A, support structure 120 is illustrated supporting a substrate 118. Bonding tool 110 is illustrated having formed a bond 116a (e.g., a first bond) from wire 116 at a bonding location (e.g., a first bonding location). Wire 116 is provided by wire guide 114 (e.g., prior to, during, and/or after forming bond 116a).

Referring now to FIG. 2B, a length of wire has been extended from bond 116a to form a wire loop 116b including a second bond 116c. After second bond 116c is formed, a cutting operation may be completed. Referring now to FIG. 2C, cutting blade 112 is illustrated being lowered (e.g., by motion system 106) in connection with the cutting operation. Prior to the cutting operation, a portion of cutting blade 112 (e.g., a face, a point of intersection, etc.) may contact a portion (e.g., a portion which will not be cut) of wire 116 (e.g., see FIGS. 3C and 3D). Further, prior to the cutting operation, cutting blade 112 may contact bonding tool 110 (e.g., see FIG. 3E). In FIG. 2C, cutting blade 112 is illustrated cutting into (e.g., penetrating, etc.) wire 116. Cutting blade 112 may continue to cut into wire 116 until a certain threshold is reached (e.g., when a resistance threshold is reached, when a depth threshold is reached, when 65%-85% of the wire diameter is cut, when 75% of the wire diameter is cut, etc.).

Referring now to FIG. 2D, bond head assembly 102 (not shown in FIGS. 2A-2D, but see FIG. 1) has moved laterally (e.g., to the right along the x-axis) and vertically (e.g., upwards along the z-axis) after a cutting operation, such that bonding tool 110, cutting blade 112, and wire guide 114 are illustrated away from wire loop 116b. As shown in FIG. 2D, a wire tail 116d is shown below bonding tool 110 for use in connection with the formation of a next wire loop.

Referring now to FIGS. 3A-3G, cutting blade 112 is illustrated in greater detail prior to a cutting operation (i.e., FIGS. 3A-3B) and during a cutting operation (i.e., FIGS. 3C-3G). While FIGS. 3A-3G are provided as a series of images, occurring in sequence in time, it should be understood that certain of the images may be included (or excluded) from various exemplary embodiments of the invention.

Cutting blade 112 is illustrated including a body portion 113 extending to (e.g., terminating at) a tip portion 115. A first side 122 (facing bonding tool 110) and a second side 124 (opposite first side 122) are illustrated disposed on either side of body portion 113 and/or tip portion 115. Second side 124 includes a first flat portion 126 and a second flat portion 128. First flat portion 126 (or face) may be configured to contact wire 116 prior to a cutting operation (e.g., see FIG. 3D). First flat portion 126 (e.g., a face) and second flat portion 128 (e.g., a face) define an area of intersection 130 (e.g., a point, an edge, an intersection edge, a protruding area, etc.). This area of intersection 130 may be configured to contact wire prior to a cutting operation (e.g., see FIG. 3C). First side 122 and second side 124 (especially first flat portion 126) define a tip 132 (e.g., a point, a cutting edge, etc.). Tip 132 can be used to cut into wire 116 at a desired cut location 136 adjacent to an edge 134 of bonding tool 110. First flat portion 126 is illustrated configured at a first angle α with respect to vertical axis 104 (of wire bonding system 100). Second flat portion 128 is illustrated configured at a second angle β with respect to vertical axis 104. As illustrated, first angle α is different from second angle β; specifically, in the illustrated embodiment, first angle α is greater than second angle β. Wire 116 is provided at a third angle Ø (e.g., 20°-60°, ~40°, etc.) with respect to vertical axis 104 (e.g., see FIG. 3B). More specifically, after formation of a wire loop but before the cutting operation, a wire portion adjacent the tip of the cutting blade defines an angle Ø with respect to the vertical axis of the wire bonding system. This wire angle Ø may be less than first angle α. Further, second angle β may be less then third angle Ø.

Described in sequence, FIGS. 3A-3B illustrate cutting blade 112 after formation of second bond 116c (see FIG. 2B). FIGS. 3C-3G illustrate the lowering of cutting blade 112, and the cutting operation of wire 116. FIG. 3C illustrates area of intersection 130 contacting wire 116 prior to the cutting operation (where the cutting operation is shown in FIGS. 3F-3G). As cutting blade 112 is further lowered as shown in FIG. 3D, first flat portion 126 (e.g., a face) contacts wire 116 prior to the cutting operation (where the cutting operation is shown in FIGS. 3F-3G). First flat portion 126 may provide higher resistance to cutting blade 112 to prevent overcut of wire 116, when cutter blade 112 is close to the “deep limit” (e.g., >85% of the wire diameter). As cutting blade 112 is further lowered as shown in FIG. 3E, cutting blade 112 may contact bonding tool 110 prior to (and/or during, and/or after) the cutting operation. FIGS. 3F-3G illustrate the cutting operation (similar to that shown in FIG. 2C).

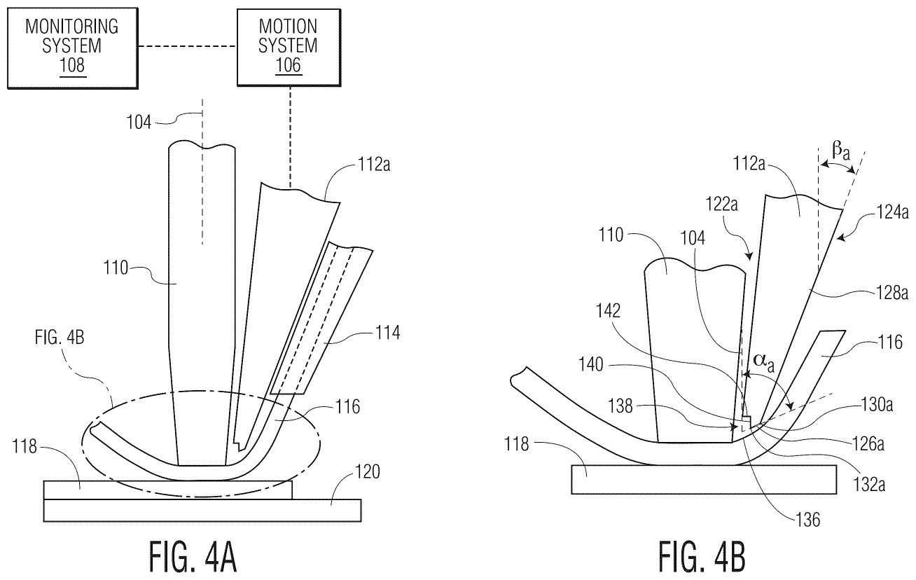

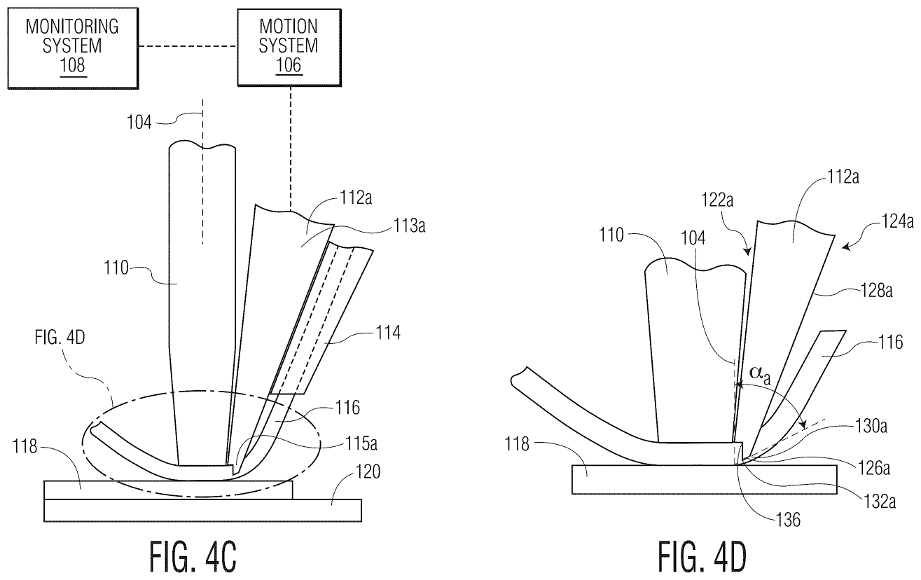

As provided above, cutting blades in accordance with aspects of the invention may include a “stepped” portion. Referring specifically to FIGS. 4A-4D, cutting blade 112a is illustrated prior to a cutting operation (i.e., FIGS. 4A-4B) and during a cutting operation (i.e., FIGS. 4C-4D). Cutting blade 112a is similar to cutting blade 112 (with various of the features described above with respect to FIGS. 2A-2D and FIGS. 3A-3G), except cutting blade 112a includes stepped portion 138. Stepped portion 138 is illustrated defining a 90 degree angle; however, it should be understood that stepped portion 138 may define any angle between 0 and 180 degrees. Certain exemplary ranges include: 80 to 100 degrees; 70 to 110 degrees; 60 to 120 degrees; and 50 to 130 degrees. It should be understood that the angle defined by stepped portion may include a curved, filleted, and/or chamfered shape, whereby the angle can be understood as defined by one or more tangent lines of the curved, filleted, and/or chamfered shape (e.g., at or near the termination points of such a curved, filleted, and/or chamfered shape).

Cutting blade 112a is illustrated including a body portion 113a extending to (e.g., terminating at) a tip portion 115a (e.g., see FIG. 4C). A first side 122a (facing bonding tool 110) and a second side 124a (opposite first side 122a) are illustrated disposed on either side of body portion 113a and/or tip portion 115a. Second side 124a includes a first flat portion 126a and a second flat portion 128a. First flat portion 126a (or face) may be configured to contact wire 116 prior to a cutting operation. First flat portion 126a (e.g., a face) and second flat portion 128a (e.g., a face) define an area of intersection 130a (e.g., an edge, an intersection edge, a protruding area, etc.). First side 122a and second side 124a (especially first flat portion 126a) define a tip 132a (e.g., a point, a cutting edge, etc.). Tip 132a can be used to cut into wire 116 at a desired cut location 136 adjacent to an edge 134 of bonding tool 110. First flat portion 126a is illustrated configured at a first angle αₐ with respect to vertical axis 104 (of wire bonding system 100). Second flat portion 128a is illustrated configured at a second angle βₐ with respect to vertical axis 104. As illustrated, first angle αₐ is different from second angle βₐ; specifically, first angle αₐ is at a greater angle than second angle βₐ. Stepped portion 138 includes a step height 140 and a step width 142. Step height 140 can be designed as a predetermined percentage (e.g., 75%) of the wire diameter such that the cutting blade 112a can cut up to the predetermined percentage (e.g., 75%) of wire diameter. The predetermined percentage can be within a desired cut depth range (e.g., 65% to 85% of wire diameter). Step width 142 has several functions, including physically preventing cutting blade 112a from going deeper into wire 116 and generating a motion control signal to stop the drive (e.g., using a motor) of the cut motion.

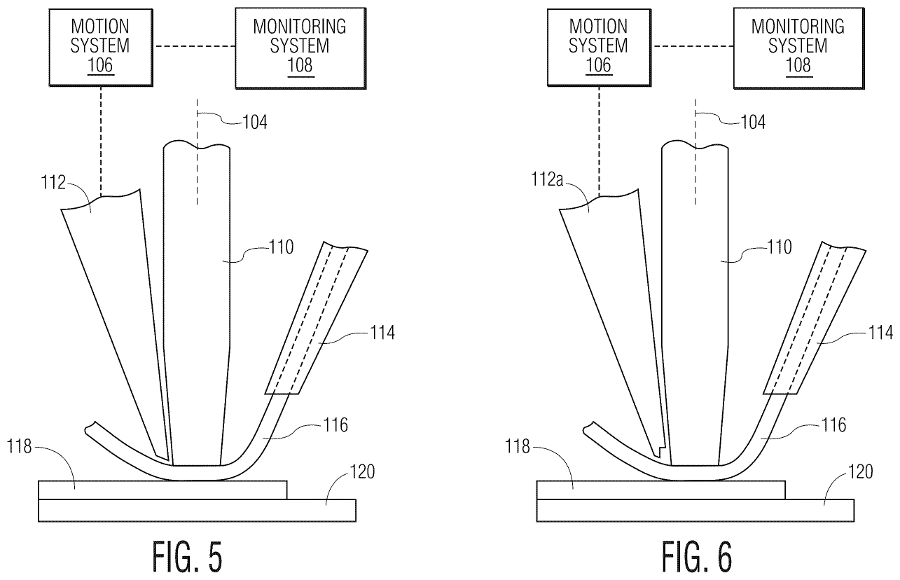

FIGS. 2A-2D, 3A-3G, and 4A-4D illustrate a “rear cut” condition (i.e., where the conductive material is cut on the side of the bonding near the wire guide 114). The invention is not so limited to “rear cut” applications. FIGS. 5 and 6 illustrate, respectively, cutting blade 112 and cutting blade 112a in a “front cut” application. Specifically, cutting blade 112 and cutting blade 112a are illustrated prior to a cutting operation.

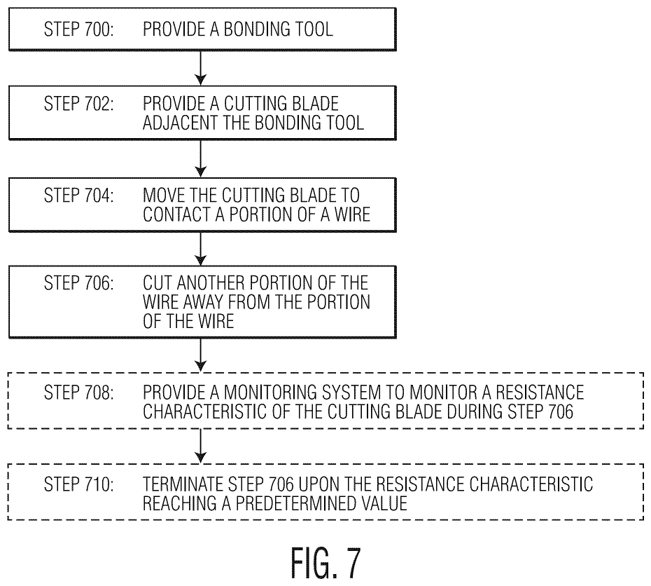

FIG. 7 is a flow diagram in accordance with certain exemplary embodiments of the invention. As is understood by those skilled in the art, certain steps included in the flow diagram may be omitted; certain additional steps may be added; and the order of the steps may be altered from the order illustrated. Dashed lines may be considered as “optional” in certain embodiments.

FIG. 7 is a flow diagram illustrating a method of cutting a wire in connection with a wire bonding system. At Step 700, a bonding tool (e.g., bonding tool 110) is provided. At Step 702, a cutting blade (e.g., cutting blade 112, cutting blade 112a, etc.) is provided adjacent the bonding tool. At Step 704, the cutting blade is moved to contact a portion of a wire (e.g., wire 116) (e.g., see area of intersection 130 contacting wire 116 in FIG. 3C, and first flat portion 126 contacting wire 116 in FIG. 3D). At Step 706, another portion of the wire is cut away from the portion of the wire using the cutting blade (e.g., see a different point of wire 116 being cut in FIG. 3E, as compared to the points of contact in FIG. 3C and FIG. 3D). At optional Step 708, a monitoring system is provided to monitor a resistance characteristic of the cutting blade during Step 706. At optional Step 710, the cutting (of Step 706) is terminated upon the resistance characteristic reaching a predetermined value (e.g., a current reading of a motor exceeding a predefined threshold, a signal corresponding to a frictional or mechanical resistance of the cutting blade exceeding a predefined threshold, etc.).

Through the various embodiments of the invention, well controlled cutting processes (e.g., resulting in an accurate cut depth, and consistent tail lengths) are provided. Certain cutting blades and associated control systems of the invention make the cutting process stable and consistent. Further, the cut location can be kept at an optimal location, resulting in a consistent tail length and cut depth. Control of the cut depth prevents under-cut (e.g., where wire is not terminated and the bond process stops) or over-cut (e.g., where no wire is fed to the bond tool). Further still, certain embodiments of the invention can provide advantages such as a wider cut window, more accurate cut depth, more consistent tail length, higher throughput, and higher yield.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A wire bonding system comprising:
a bonding tool; and
a cutting blade disposed adjacent to the bonding tool, the cutting blade defining a face on a side of the cutting blade adjacent a tip of the cutting blade, the face configured to contact wire prior to a cutting operation.

2. The wire bonding system of claim 1 wherein after a wire bonding operation is complete, the cutting blade is configured to contact the bonding tool prior to the cutting operation.

3. The wire bonding system of claim 1 wherein after a wire bonding operation is complete, the cutting blade is configured to contact the bonding tool during the cutting operation.

4. The wire bonding system of claim 1 wherein the face is configured to provide resistance to the cutting blade to prevent overcut of a wire.

5. The wire bonding system of claim 1 wherein the cutting blade defines another side, the another side facing the bonding tool, the another side being opposite the side, the side defining another face adjacent the face, the face and the another face meeting at an area of intersection, the face and the another face being non-parallel to each other.

6. The wire bonding system of claim 1 wherein the cutting blade defines another side, the another side facing the bonding tool, the another side being opposite the side, the side defining another face adjacent the face, the face being configured at a first angle with respect to a vertical axis on the wire bonding system, the another face being configured at a second angle with respect to the vertical axis of the wire bonding system, the first angle being different from the second angle.

7. The wire bonding system of claim 6 wherein the first angle is greater than the second angle.

8. The wire bonding system of claim 6 further comprising a wire guide configured to direct a wire toward a position beneath the bonding tool, wherein after formation of a wire loop but before a cutting operation, a wire portion adjacent the tip of the cutting blade defines a third angle with respect to the vertical axis of the wire bonding system, the first angle being greater than the third angle.

9. The wire bonding system of claim 1 further comprising a monitoring system for monitoring a resistance characteristic of the cutting blade as the cutting blade cuts into a wire on the wire bonding system.

10. The wire bonding system of claim 9 further comprising a motion system configured to raise and lower the cutting blade for cutting a wire on the wire bonding system.

11. The wire bonding system of claim 10 wherein the resistance characteristic is related to an electrical characteristic of the motion system.

12. The wire bonding system of claim 10 wherein the resistance characteristic is related to at least one of an electrical current of the motion system, a velocity of a portion of the motion system, and a position of a portion of the motion system.

13. The wire bonding system of claim 10 wherein the motion system is configured to stop lowering of the cutting blade upon the resistance characteristic reaching a predetermined value.

14. The wire bonding system of claim 1 wherein the tip includes a stepped portion configured to limit penetration of the cutting blade into a wire during a cutting operation.

15. A wire bonding system comprising:
a bonding tool; and
a cutting blade disposed adjacent to the bonding tool, the cutting blade defining a first side and a second side, the first side facing the bonding tool, the second side being opposite the first side, the second side defining a first flat portion adjacent a tip of the cutting blade and a second flat portion adjacent the first flat portion, the first flat portion and the second flat portion meeting at an area of intersection, the first flat portion and the second flat portion being non-parallel to each other, wherein the area of intersection is configured to contact wire prior to a cutting operation.

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. A method of cutting a wire in connection with a wire bonding system comprising the steps of:
(a) providing a bonding tool;
(b) providing a cutting blade adjacent the bonding tool;
(c) moving the cutting blade to contact a portion of the wire; and
(d) cutting another portion of the wire away from the portion of the wire.

41. The method of claim 40 wherein step (c) includes contacting the bonding tool with the cutting blade prior to step (d).

42. The method of claim 40 wherein step (c) includes contacting the bonding tool with the cutting blade during step (d).

43. The method of claim 40 further comprising the step of (e) providing a monitoring system to monitor a resistance characteristic of the cutting blade during step (d).

44. The method of claim 43 further comprising the step of terminating step (d) upon the resistance characteristic reaching a predetermined value.
